(19) United States
(12) Patent Application Publication
(10) Pub. No.: US 2022/0373648 A1
(43) Pub. Date: Nov. 24, 2022

(54) DISTANCE SENSOR MODULE

(71) Applicant: AMOSENSE CO.,LTD, Cheonan-si, Chungcheongnam-do (KR)

(72) Inventor: Byungguk LIM, Incheon (KR)

(73) Assignee: AMOSENSE CO.,LTD, Cheonan-si, Chungcheongnam-do (KR)

(21) Appl. No.: 17/770,897

(22) PCT Filed: Sep. 24, 2020
(86) PCT No.: PCT/KR2020/012978

§ 371 Date: Apr. 21, 2022

(30) Foreign Application Priority Data
Oct. 22, 2019 (KR) 10-2019-0131138

(51) Int. Cl. G01S 7/481

(52) U.S. Cl. CPC G01S 7/481

(57) ABSTRACT

The present invention comprises: a circuit board; a laser diode mounted on the circuit board; a photodiode mounted on the circuit board; and a drive integrated circuit which is mounted on the circuit board and drives the laser diode and the photodiode, wherein the circuit board includes a circuit forming unit in which wiring layers for electrically connecting the drive integrated circuit to the laser diode are stacked. The present invention has an advantage in that the drive integrated circuit is included in a distance sensor module so as to be manufactured as a single module, and a ferrite chip bead is included in the module so as to reduce noise.

### TECHNICAL FIELD

The present disclosure relates to a distance sensor module of a mobile terminal, and more specifically, to a TOF type distance sensor module used for proximity detection and distance measurement by radiating a laser.

### BACKGROUND ART

Time of flight (TOF) type distance sensor modules are applied to recently released smartphones. The TOF type distance sensor modules recognize spatial information, movement, etc. by calculating the time it takes for the light emitted toward a subject to bounce back and return as a distance.

When the TOF type distance sensor modules are used, user authentication, motion recognition, augmented reality (AR), and virtual reality (VR) contents can be implemented without directly touching the products.

The TOF type distance sensor modules have a structure including electronic devices such as a laser diode (LD) and a photodiode (PD). In the TOF type distance sensor modules, unnecessary electromagnetic signals or electromagnetic noises can be generated inside the electronic device or in external wires connected to the electronic devices.

In order to minimize these electromagnetic noises, as shown in FIG. 1, a TOF type distance sensor module 10 has a shield can 11 for electromagnetic shielding installed on the uppermost portion.

However, there is a problem in that since the conventional TOF type distance sensor module 10 is connected to a drive integrated circuit (IC) 15 through a cable 13, the cable 13 acts as a radiator to generate unnecessary electromagnetic signals or electromagnetic noises.

Unnecessary electromagnetic signals or electromagnetic noises can be referred to as electromagnetic interference (EMI), and solutions thereof are required to improve the integration degree.

In particular, as smartphones have recently become multi-functional, electronic devices are mounted at high density, and electronic devices operate at 100 Mhz to 1 GHz for high-speed and high-capacity data communication and processing, it is necessary to overcome problems such as noises due to electromagnetic interference, malfunction of each function, and degradation of signal quality.

### DISCLOSURE

### Technical Problem

An object of the present disclosure is to provide a TOF type distance sensor module, which can be manufactured as one module by including a drive integrated circuit within a distance sensor module to constitute a cable connecting the distance sensor module to the drive integrated circuit as a wiring circuit within the module, and include a bead structure within the module, thereby reducing noises.

### Technical Solution

In order to achieve the object, a distance sensor module includes a circuit board, a laser diode mounted on the circuit board, a photodiode mounted on the circuit board, and a drive integrated circuit mounted on the circuit board and driving the laser diode and the photodiode, in which the circuit board includes a circuit forming unit in which wiring layers for electrically connecting the drive integrated circuit to the laser diode are stacked.

The circuit forming unit can include a ferrite layer printed by pasting a ferrite between the wiring layer and the wiring layer in order to increase a mutual inductance.

The distance sensor module can include a spiral coil circuit unit stacked under the circuit board, in which the spiral coil circuit unit can include an inductor having a bead structure formed by patterning a coil on the ferrite layer.

The distance sensor module can include an interposer disposed under the circuit board to secure a height of the circuit board.

A shielding material can be disposed by surrounding an outer surface of the interposer.

The interposer can be formed in a ‘ [symbol] ’-shaped cross-sectional structure with an opened lower portion, and a ferrite chip bead can be mounted on a bottom surface of the interposer.

The interposer can be formed in a ‘ [symbol] ’-shaped cross-sectional structure having a space with an opened lower portion, and a ferrite chip bead and an MLCC can be mounted on a bottom surface of the interposer and disposed in the space.

The interposer can be formed by bonding both a ‘ [symbol] ’-shaped cross-sectional structure having a space with an opened lower portion and a ‘ [symbol] ’-shaped cross-sectional structure having a space with an opened upper portion, and a ferrite chip bead can be mounted on one of the two structures to be disposed in the space.

The interposer is formed in a rectangular shape opened up and down, and a ferrite chip bead can be mounted on the lower portion of the circuit board corresponding to the space surrounded and formed by the interposer.

### Advantageous Effects

Since the distance sensor module according to the present disclosure can be manufactured as one module by including the drive integrated circuit within the distance sensor module, it is possible to solve the problem of generating an electromagnetic signals or electromagnetic interference (EMI) through the cable connecting the conventional distance sensor module to the drive integrated circuit.

The distance sensor module according to the present disclosure can secure the height of the circuit board including the interposer to match the height with the surrounding cameras, and shorten the conducting wires and dispose the shielding material on the outer surface of the interposer to reduce noises.

In addition, according to the present disclosure, it is possible to solve the EMI problem by securing the space with the interposer to mount the ferrite bead chip on the interposer or the bottom surface of the circuit board to reduce noises.

In addition, according to the present disclosure, it is possible to solve the EMI problem by forming the bead structure of the spiral coil circuit unit between the circuit board and the interposer to reduce noises.

In addition, according to the present disclosure, it is possible to dispose the ferrite layer between the wiring layers formed on the circuit board to increase the mutual inductance, thereby reducing noises.

### DESCRIPTION OF DRAWINGS

FIG. 1 is a picture showing a conventional TOF type distance sensor module.

FIG. 2 is a conceptual diagram showing a distance sensor module according to an embodiment of the present disclosure.

FIG. 3 is a side diagram showing the distance sensor module according to the embodiment of the present disclosure.

FIGS. 4 and 5 are cross-sectional diagrams showing a circuit forming unit of the distance sensor module according to the embodiment of the present disclosure.

FIG. 6 is a cross-sectional diagram of the distance sensor module according to the embodiment of the present disclosure.

FIG. 7 is a cross-sectional diagram of a distance sensor module according to another embodiment of the present disclosure.

FIG. 8 is a cross-sectional diagram of a distance sensor module according to still another embodiment of the present disclosure.

FIG. 9 is a cross-sectional diagram of a distance sensor module according to yet another embodiment of the present disclosure.

FIG. 10 is a cross-sectional diagram of a distance sensor module according to still yet another embodiment of the present disclosure.

FIG. 11 is a cross-sectional diagram of a distance sensor module according to further another embodiment of the present disclosure.

### BEST MODE

Hereinafter, embodiments of the present disclosure will be described in detail with reference to the accompanying drawings.

A distance sensor module 100 according to the present disclosure is a TOF type distance sensor module. The distance sensor module 100 is manufactured in the form of one module by including a drive integrated circuit 140 within the distance sensor module 100.

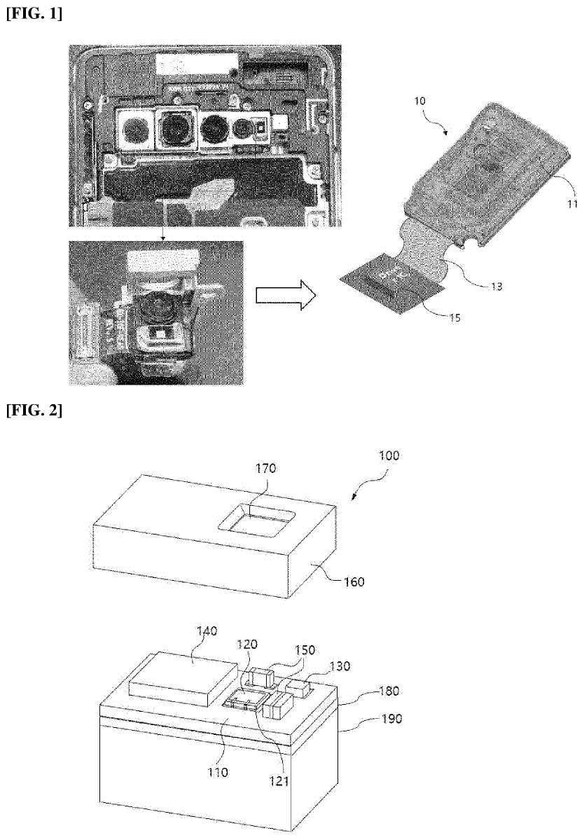

When the drive integrated circuit 140 is included in the distance sensor module 100, it is possible to solve electromagnetic signals or electromagnetic interference (EMI) generation problems through a cable (reference numeral 13 in FIG. 1) connecting the conventional distance sensor module to the drive integrated circuit.

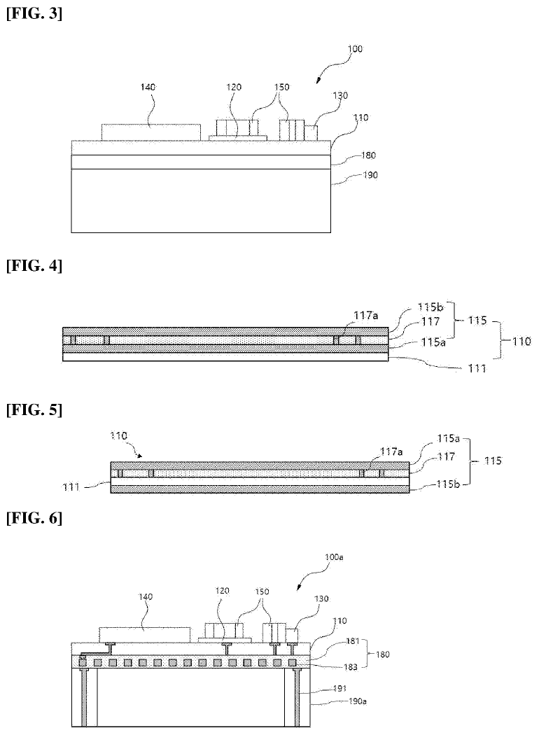

As shown in FIGS. 2 and 3, the distance sensor module 100 has a laser diode (LD) 120, a photodiode (PD) 130, the drive integrated circuit 140, and a multi-layer ceramic capacitor (MLCC) 150 mounted on a circuit board 110.

The laser diode 120 is an electronic device that emits light. A vertical-cavity surface-emitting laser (VCSEL) can be applied to the laser diode 120. The laser diode 120 can be coupled to an upper housing and grounded to prevent noises from being introduced.

A window member 121 for emitting light discharged from the laser diode 120 can be provided on a rim of the upper housing coupled to the laser diode 120, and an antenna pattern can be included on the rim. The light emission is for the safety of the user's eyes.

The photodiode 130 is an electronic device that measures a low PD current in order to identify the intensity of a light source. The photodiode 130 can check whether the laser diode 120 is damaged by identifying the intensity of the light source.

The drive integrated circuit 140 is an integrated circuit that drives the laser diode 120, the photodiode 130, etc. The drive integrated circuit 140 includes a drive circuit connecting the drive integrated circuit 140 to the laser diode 120, the photodiode 130, etc.

The MLCC 150 is a multi-layer ceramic capacitor, and serves to store electricity and supply electricity to each electronic device, as necessary. The MLCC 150 supplies power so that the laser diode 120, the photodiode 130, etc. are stably operated.

A shield can 160 for shielding electromagnetic waves is coupled to an upper portion of the circuit board 110. The shield can 160 is provided with a micro lens array 170 for light emission.

The circuit board 110 includes a circuit forming unit including the drive circuit that connects the drive integrated circuit 140 to the laser diode 120, the photodiode 130, etc. and a sensor circuit that interconnects the laser diode 120, the photodiode 130, the MLCC, etc.

As shown in FIG. 4, the circuit forming unit 115 can be formed of two or more wiring layers 115a, 115b, and can include a ferrite layer 117 printed by pasting a ferrite between a wiring layer 115a and a wiring layer 115b in order to increase a mutual inductance.

The ferrite layer 117 includes a via hole 117a so that the upper wiring layer 115b and the lower wiring layer 115a with respect to the ferrite layer 117 can be connected to each other.

For example, noises are induced through a power line, thereby causing an EMI problem in a circuit diagram of the vertical-cavity surface-emitting laser (VCSEL). The noises can be reduced by designing the length of a conducting wire as short as possible, but this is physically limited.

Accordingly, the noises are reduced by minimizing a total inductance.

Since the total inductance is [the self-inductance (the length of the conducting wire)—the mutual inductance], it is possible to reduce the total inductance by increasing the mutual inductance. In order to increase the mutual inductance, the pasted ferrite is printed between the wiring layer 115a and the wiring layer 115b.

For example, the wiring layer 115a is printed on a substrate 111, the ferrite layer 117 is printed on the wiring layer 115a, and the wiring layer 115b is printed on the ferrite layer 117 so that the ferrite layer 117 can be included between the wiring layer 115a and the wiring layer 115b.

As shown in FIG. 5, the wiring layer 115a can be directly printed and formed on the ferrite layer 117.

For example, the ferrite layer 117 is attached to the entire upper surface of the substrate 111 in the form of a sheet, the wiring layer 115a is formed on the ferrite layer 117, and the wiring layer 115b is formed under the substrate 111 so that the ferrite layer 117 can be included between the wiring layer 115a on the substrate 111 and the wiring layer 115b under the substrate 111 with respect to the substrate 111. Here, the ferrite layer 117 is formed with a via hole 117a so that the wiring layers 115a, 115b can be connected to each other. A structure of the via in the substrate 111 is omitted.

The substrate 111 can use both a ceramic material such as a low temperature co-fired ceramic (LTCC), a high temperature co-fired ceramic (HTCC), or an aluminium nitride (AlN), and a resin material such as FR4.

As shown in FIG. 6, the distance sensor module 100 can include a spiral coil circuit unit 180 under the circuit board 110. The spiral coil circuit unit 180 is to remove noises. The spiral coil circuit unit 180 is formed by patterning a coil 183 on a ferrite layer 181 to form an inductor having a bead structure. The ferrite layer 181 of the spiral coil circuit unit 180 removes the noises by reflecting or absorbing the noises that distort the waveform.

One or more coils 183 are connected to the circuit forming unit 115. In addition, one or more coils 183 are connected to an interposer 190 below.

The interposer 190 is disposed under the spiral coil circuit unit 180. The interposer 190 is configured to increase the height of the circuit board 110 in order to match the height of the distance sensor module 100 with the heights of cameras disposed adjacent thereto.

The conducting wire can be configured with the shortest distances when both the drive circuit that connects the drive integrated circuit 140 to the laser diode 120, the photodiode 130, etc. and the sensor circuit that interconnects the laser diode 120, the photodiode 130, the MLCC 150, etc. are included in the circuit board 110 and the circuits are vertically moved downward. Since the generation of noises increases when the length of the conducting wire is increased, the generation of noises can be reduced when the conducting wire is configured with the shortest distance.

The interposer 190 includes a vertical electrode 191 that connects the circuit board 110 to a lower substrate. One or more vertical electrodes 191 can be connected to at least one of the coils 183 of the circuit forming unit 115.

The interposer 190 can be formed by using a ceramic material such as LTCC, HTCC, or AlN, or a resin material such as FR4.

Like the circuit board 110, the interposer 190 can be configured as a single body in a whole shape using FR4 or ceramic. The interposer 190 can be connected to the spiral coil circuit unit 180, including one or more vertical electrodes 191.

Although FIG. 6 shows that the spiral coil circuit unit 180 is included between the circuit board 110 and the interposer 190, the interposer 190 can be disposed under the circuit board 110 in the form of omitting the spiral coil circuit unit 180, and the vertical electrode 191 of the interposer 190 can be connected to the circuit forming unit (reference numeral 115 in FIG. 4) of the circuit board 110. In this case, the ferrite layer (reference numeral 117 in FIG. 4) included in the circuit forming unit 115 can serve to reduce noises.

A shielding material is disposed on the outer surface of the interposer 190 in order to shield electromagnetic waves. The shielding material can be a conductive shielding material, and formed by plating, spraying zinc, or applying, coating, or printing a conductive paint on the outer surface of the interposer 190. Alternatively, the shielding material can be formed on the outer surface of the interposer 190 by a sputtering method.

The distance sensor module 100 shown in FIG. 6 includes the circuit forming unit 115 on the circuit board 110, and the spiral coil circuit unit 180 can be disposed between the interposer 190 and the circuit board 110 to form the bead structure, thereby removing noises. Here, as shown in FIG. 4, the circuit forming unit 115 can include the ferrite layer 117 printed by pasting a ferrite between the wiring layer 115a and the wiring layer 115b.

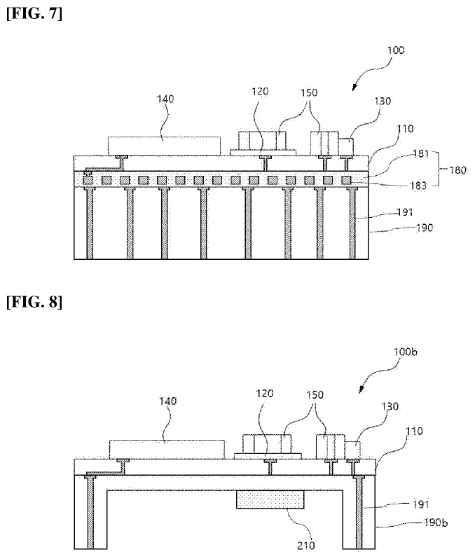

As shown in FIG. 7, a distance sensor module 100a according to another embodiment can have a shape in which an interposer 190a is formed in a rectangular rim shape with a vertical opening, and vertical electrodes 191 are formed along the rim. Another embodiment is different from the embodiment in that the shape of the interposer 190a has an internal space.

Chip components such as a chip bead and an MLCC can be mounted in the internal space of the interposer 190a. In addition, when the interposer 190a is made of LTCC or other ceramic materials, a circuit can be formed in the internal space of the interposer 190a to integrally constitute a passive element of a capacitor such as an MLCC, examples of which will be described below.

As shown in FIG. 8, a distance sensor module 100b according to still another embodiment can be formed in a structure in which an interposer 190b is formed in a ‘ [symbol] ’-shaped cross-sectional structure with an opened lower portion, and a chip bead is mounted on a bottom surface of the internal space of the interposer 190a.

The interposer 190b having the ‘ [symbol] ’-shaped cross-sectional structure has a strength-reinforcing effect that supports the circuit board 110, and provides the internal space thereunder to mount the chip bead. The distance sensor module 100 has a very narrow space with about 5 mm in width and length. Accordingly, there is no space capable of placing the bead on the circuit board 110 in the form of a chip. On the other hand, since the interposer 190b has the empty internal space in the middle, the interposer 190b can be formed in the ‘ [symbol] ’-shaped cross-sectional structure to mount the chip bead 210 on the bottom surface thereof. The chip bead 210 is made of ferrite. The chip bead 210 can be manufactured by alternately stacking a ferrite (sheet or paste) and an electrode paste.

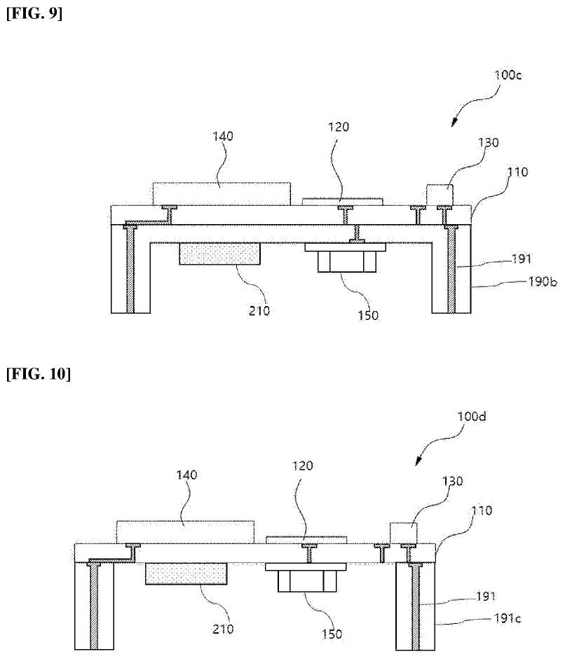

As shown in FIG. 9, as yet another embodiment, a distance sensor module 100c can be formed in a structure in which an interposer 190c is formed in the ‘ [symbol] ’-shaped cross-sectional structure with an opened lower portion, and the chip bead 210 and the MLCC 150 are mounted on the bottom surface of the internal space of the lower portion of the interposer 190a.

When the chip bead 210 and the MLCC 150 are mounted on the lower surface of the interposer 190b, the mounting space of the MLCC can be reduced on the upper surface of the circuit board 110, thereby further reducing the size of the distance sensor module 110c. One or more MLCCs 150 can be mounted on the bottom surface of the interposer 190b.

As shown in FIG. 10, as still yet another embodiment, a distance sensor module 100d can be formed in a structure in which the interposer 190 is formed in a rectangular shape with opened upper and lower portions, and the ferrite chip bead 210 and the MLCC 150 are mounted on the bottom surface of the circuit board 110.

In this case, the strength reinforcement effect by the interposer 190c is lower than that of the ‘ [symbol] ’-shaped cross-sectional structure shown in FIG. 9, but it is possible to reduce the mounting space of the MLCC on the upper surface of the circuit board 110, thereby further reducing the size of the distance sensor module 100d.

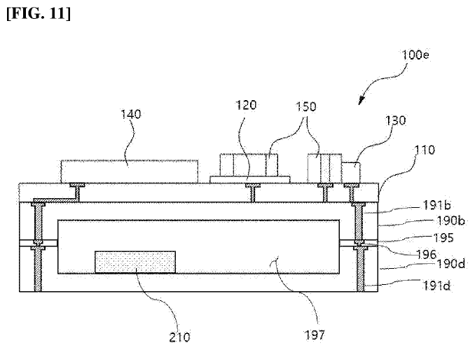

As shown in FIG. 11, as further another embodiment, a distance sensor module 100e can be formed by bonding the interposer 190b having the ‘ [symbol] ’-shaped cross-sectional structure with the opened lower portion and the interposer 190d having the ‘ [symbol] ’-shaped cross-sectional structure with the opened upper portion with an epoxy 195.

The two interposers 190b, 190d include vertical electrodes 191b, 191d, and the epoxy 195 includes a connection electrode 196 so that the two vertical electrodes 191b, 191d can be interconnected.

The ferrite chip bead 210 is disposed in an internal space 197 formed between the two interposers 190b, 190d. At this time, the ferrite chip bead 210 can be disposed in the space 197 in a state of being mounted on at least one of the interposer 190b having the ‘ [symbol] ’-shaped cross-sectional structure with the opened lower portion and the interposer 190d having the ‘ [symbol] ’-shaped cross-sectional structure with the opened upper portion.

The present disclosure has the basic feature that the laser diode 120, the photodiode 130, the drive integrated circuit 140, and the MLCC 150 are formed on the circuit board 110, includes the circuit forming unit 115 in which the wiring layers 115a, 115b for electrically connecting the drive integrated circuit to the laser diode are stacked in the circuit board 110, includes the ferrite layer 117 between the wiring layers 115a, 115b, and disposes the interposer 190 under the circuit board 110, thereby securing the height of the circuit board 110.

In addition, the present disclosure has the additional feature that the spiral coil circuit unit 180 can be included between the circuit board 110 and the interposer 190 to reduce noises.

In addition, the present disclosure has the additional feature that it is possible to solve the EMI problem by configuring the interposer in the rim shape with opened upper and lower portions, the ‘ [symbol] ’-shaped cross-sectional shape with the opened lower portion, etc., to form the internal space, and mounting the chip bead, the MLCC, etc. in the internal space to reduce the volume of the distance sensor module and reduce noises.

The present disclosure has been described by classifying the shape for each embodiment using the aforementioned one embodiment as the basic structure, but combinations thereof can be applied.

The present disclosure has disclosed the optimal embodiments in the drawings and the specification. Here, the specific terms have been used but this is merely used for the purpose of describing the present disclosure and not used for limiting the meaning or the scope of the present disclosure described in the claims. Accordingly, those skilled in the art will understand that various modifications and other equivalent embodiments from the present disclosure can be possible. Accordingly, the true technical scope of the present disclosure should be determined by the technical spirit of the appended claims.

1. A distance sensor module comprising:
a circuit board;
a laser diode mounted on the circuit board;
a photodiode mounted on the circuit board; and
a drive integrated circuit mounted on the circuit board and driving the laser diode and the photodiode,
wherein the circuit board comprises a circuit forming unit in which wiring layers for electrically connecting the drive integrated circuit to the laser diode are stacked.

2. The distance sensor module of claim 1,
wherein the circuit forming unit comprises a ferrite layer printed by pasting a ferrite between the wiring layer and the wiring layer in order to increase a mutual inductance.

3. The distance sensor module of claim 1,
comprising: a spiral coil circuit unit stacked under the circuit board,
wherein the spiral coil circuit unit is an inductor having a bead structure formed by patterning a coil on the ferrite layer.

4. The distance sensor module of claim 1,
comprising: an interposer disposed under the circuit board to secure a height of the circuit board.

5. The distance sensor module of claim 4,
wherein a shielding material is disposed by surrounding an outer surface of the interposer.

6. The distance sensor module of claim 4,
wherein the interposer is formed in a ‘ [symbol] ’-shaped cross-sectional structure with an opened lower portion, and
a ferrite chip bead is mounted on a bottom surface of the interposer.

7. The distance sensor module of claim 4,
wherein the interposer is formed in a ‘ [symbol] ’-shaped cross-sectional structure having an internal space with an opened lower portion, and
a ferrite chip bead and an MLCC are mounted on a bottom surface of the interposer and disposed in the internal space.

8. The distance sensor module of claim 4,
wherein the interposer is formed by bonding both a ‘ [symbol] ’-shaped cross-sectional structure having an internal space with an opened lower portion and a ‘ [symbol] ’-shaped cross-sectional structure having an internal space with an opened upper portion, and
a ferrite chip bead is mounted on at least one of the two structures to be disposed in the internal space.

9. The distance sensor module of claim 4,
wherein the interposer is formed in a rectangular shape opened up and down, and
a ferrite chip bead is mounted under the circuit board corresponding to the internal space surrounded and formed by the interposer.
